(19) United States
(12) Patent Application Publication
(10) Pub. No.: US 2009/0311634 A1
(43) Pub. Date: Dec. 17, 2009

(54) METHOD OF DOUBLE PATTERNING USING SACRIFICIAL STRUCTURE

(75) Inventors: Hongyu Yue, Plano, TX (US); Hieu A. Lam, Richardson, TX (US); Reiji Niino, Nirasaki City (JP)

Correspondence Address: WOOD, HERRON & EVANS, LLP (TOKYO ELECTRON), 2700 CAREW TOWER, 441 VINE STREET, CINCINNATI, OH, 45202, US

(73) Assignee: TOKYO ELECTRON LIMITED, Tokyo (JP)

(21) Appl. No.: 12/137,183

(22) Filed: Jun. 11, 2008

(51) Int. Cl. G03F 7/004

(52) U.S. Cl. 430/323

(57) ABSTRACT

A method of patterning a thin film on a substrate is described. The method includes forming a sacrificial structure over the thin film, and forming a photo-resist layer over the sacrificial structure. The sacrificial structure has anti-reflective properties, comprises silicon and is capable of withstanding the photo-resist layer removal process and the stress induced during the spacer layer deposition. Thereafter, an image pattern is formed in one or both of the sacrificial structure or the photo-resist layer. A spacer layer is then conformally deposited over the pattern. The spacer layer is etched back to remove horizontal portions while substantially leaving vertical portions. The remaining photo-resist and/or sacrificial structure that is not overlaid with the etched-back spacer layer is removed leaving spacers that are utilized to transfer another pattern to the thin film.

### BACKGROUND OF THE INVENTION

1. Field of the Invention

The present invention relates to a method of patterning a thin film on a substrate, and more particularly to a method of using a sacrificial structure and conformal deposition to pattern a thin film on a substrate.

2. Description of the Related Art

In material processing methodologies, pattern etching comprises the application of a thin layer of light-sensitive material, such as photo-resist, to an upper surface of a substrate that is subsequently patterned in order to provide a mask for transferring this pattern to the underlying thin film on a substrate during etching. The patterning of the light-sensitive material generally involves exposure by a radiation source through a reticle (and associated optics) of the light-sensitive material using, for example, a photo-lithography system, followed by the removal of the irradiated regions of the light-sensitive material (as in the case of positive photo-resist), or non-irradiated regions (as in the case in negative resist) using a developing solvent. Moreover, this mask layer may comprise multiple sub-layers.

More recently, in order to meet the increasing demand to produce smaller features, the use of double patterning technologies have become more prevalent. There are two dominant methods for double patterning: (1) sidewall or spacer processes and (2) double lithography processes. In the spacer process, the spacer is used as the final mask to create the final pattern in the thin film. The spacer is generated in a multi-layer mask. The mask layer typically comprises a light-sensitive material, such as a photo-resist layer, that is patterned using conventional photo-lithography techniques. The multi-layer mask may also include a bottom anti-reflective coating (BARC) and/or a hard mask. The pattern in the light-sensitive layer is transferred to the BARC and/or hard mask layers using etching techniques. However, current techniques for removing the light-sensitive layer may damage the BARC, leading to poor profile control and residual film left over before the spacer deposition. In addition, if the BARC does not have the mechanical properties necessary to tolerate the stresses induced during the spacer formation process, then again, poor profile control may result.

There is thus a need for an improved method of patterning thin films in which there is better etch selectivity between layers of the mask and improved profile control.

### SUMMARY OF THE INVENTION

The present invention relates to a method of forming spacers for patterning a thin film on a substrate.

According to one embodiment, a method of patterning a thin film on a substrate is described. The method comprises forming a sacrificial structure over the thin film, and forming a photo-resist layer over the sacrificial structure. The sacrificial structure comprises a silicon-containing anti-reflective coating (ARC) layer. A pattern is created in one or both of the photo-resist or the sacrificial structure. Then, a spacer layer is conformally deposited over the pattern in either the photo-resist or sacrificial structure. Thereafter, the spacer layer is etched back to remove horizontal portions of the spacer layer while substantially leaving vertical portions of the spacer layer. Following the etching back step is the removal of the remaining photo-resist or sacrificial structure that is not overlaid by the etched spacer layer.

According to another embodiment, a method of patterning a thin film on a substrate is described, comprising forming a sacrificial structure over the thin film wherein the sacrificial structure has anti-reflective qualities and comprises silicon, and forming a photo-resist layer over the sacrificial structure. A pattern is created in the photo-resist layer by imaging and developing the photoresist layer. The image pattern in the photo-resist layer is transferred to the sacrificial structure and the photo-resist layer is removed. Then, a spacer layer is conformally deposited over the pattern in the sacrificial structure. Thereafter, the spacer layer is etched back to remove horizontal portions of the spacer layer while substantially leaving vertical portions of the spacer layer. Following the etching back step is the removal of the remaining sacrificial structure that is not overlaid by the etched spacer layer.

According to another embodiment, a method of patterning a thin film on a substrate is described, comprising forming a sacrificial structure over the thin film wherein the sacrificial structure has anti-reflective qualities and comprises silicon, and forming a photo-resist layer over the sacrificial structure. A pattern is created in the photo-resist layer by imaging and developing the photo-resist layer. Then, a spacer layer is conformally deposited over the pattern in the photo-resist layer. Thereafter, the spacer layer is etched back to remove horizontal portions of the spacer layer while substantially leaving vertical portions of the spacer layer. Then, the remaining photo-resist layer is removed followed by the removal of any sacrificial structure that is not overlaid by the etched spacer layer.

### BRIEF DESCRIPTION OF THE DRAWINGS

In the accompanying drawings:

FIGS. 1A through 1F illustrate schematically a method for patterning a thin film on a substrate according to an embodiment;

FIGS. 2A through 2F illustrate schematically a method for patterning a thin film on a substrate according to another embodiment;

FIGS. 3A through 3F illustrate schematically a method for patterning a thin film on a substrate according to another embodiment;

FIGS. 4A through 4E illustrate schematically a method for patterning a thin film on a substrate according to another embodiment;

FIGS. 5A through 5E illustrate schematically a method for patterning a thin film on a substrate according to another embodiment; and

FIGS. 6A and 6B illustrate schematically the patterned thin film achieved by the method.

### DETAILED DESCRIPTION OF SEVERAL EMBODIMENTS

In the following description, for the purposes of explanation and not limitation, specific details are set forth, such as particular processes and patterning systems. However, it should be understood that the invention may be practiced in other embodiments that depart from these specific details.

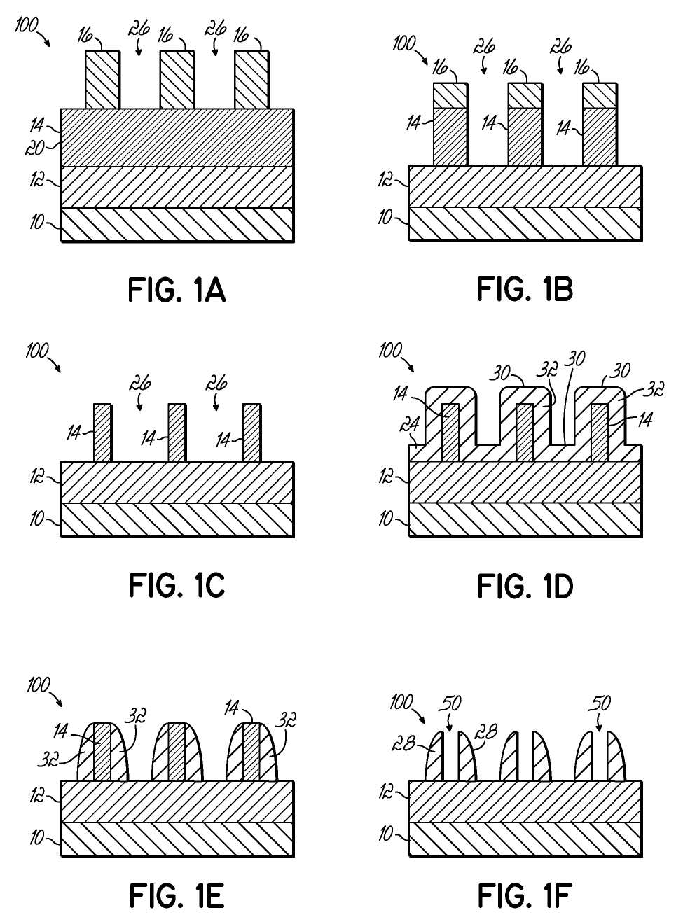

According to embodiments of the invention, illustrated in FIGS. 1A through 6B, methods of patterning a structure in a thin film 12 formed on a substrate 10 are schematically illustrated. The methods begin with forming a lithographic structure comprising a film stack 100, 200, 300, 400, and 500 formed on substrate 10. The film stack 100, 200, 300, 400, and 500 comprises a thin film 12 formed on substrate 10, a sacrificial structure 14 formed on the thin film 12, and a photo-resist layer 16 formed on the sacrificial structure 14. The sacrificial structure 14 may comprise an anti-reflective coating (ARC) layer 20 (e.g., a bottom ARC (BARC)) and may optionally include additional layers. Additionally, the sacrificial structure 14 may comprise a silicon-containing ARC layer. Further, the sacrificial structure 14 may consist of a silicon-containing ARC layer. The inventors have discovered that the use of the silicon-containing ARC layer enables double patterning of thin film 12 since the silicon-containing ARC layer provides adequate mechanical properties for withstanding the ARC layer patterning process, the conformal deposition over the standing ARC layer structures, and the subsequent removal process(es).

Additionally, for example, the sacrificial structure 14 may optionally include a hard mask layer 22, or a planarization layer, such as an organic planarization layer (OPL) disposed between the thin film 12 and the ARC layer 20.

The thin film 12 may comprise a conductive layer, a non-conductive layer, or a semi-conductive layer. For instance, the thin film 12 may include a material layer, or plurality of material layers, comprising a silicon-containing material, such as poly-silicon, silicon dioxide, silicon nitride, silicon carbide, or silicon oxynitride, etc. Additionally, for instance, the thin film 12 may comprise a low dielectric constant (i.e., low-k) or ultra-low dielectric constant (i.e., ultra-low-k) dielectric layer having a nominal dielectric constant value less than the dielectric constant of SiO₂, which is approximately 4 (e.g., the dielectric constant for thermal silicon dioxide can range from 3.8 to 3.9). More specifically, the thin film 12 may have a dielectric constant of less than 3.7, or a dielectric constant ranging from 1.6 to 3.7.

These dielectric layers may include at least one of an organic, inorganic, or inorganic-organic hybrid material. Additionally, these dielectric layers may be porous or non-porous. For example, these dielectric layers may include an inorganic, silicate-based material, such as carbon doped silicon oxide (or organo siloxane), deposited using chemical vapor deposition (CVD) techniques. Examples of such films include Black Diamond® CVD organosilicate glass (OSG) films commercially available from Applied Materials, Inc., or Coral® CVD films commercially available from Novellus Systems, Inc.

Alternatively, these dielectric layers may include porous inorganic-organic hybrid films comprised of a single-phase, such as a silicon oxide-based matrix having CH₃ bonds that hinder full densification of the film during a curing or deposition process to create small voids (or pores). Still alternatively, these dielectric layers may include porous inorganic-organic hybrid films comprised of at least two phases, such as a carbon-doped silicon oxide-based matrix having pores of organic material (e.g., porogen) that is decomposed and evaporated during a curing process.

Still alternatively, these dielectric layers may include an inorganic, silicate-based material, such as hydrogen silsesquioxane (HSQ) or methyl silsesquioxane (MSQ), deposited using spin-on dielectric (SOD) techniques. Examples of such films include FOx® HSQ commercially available from Dow Corning, XLK porous HSQ commercially available from Dow Corning, and JSR LKD-5109 commercially available from JSR Microelectronics. Still alternatively, these dielectric layers can comprise an organic material deposited using SOD techniques. Examples of such films include SiLK-I, SiLK-J, SiLK-H, SiLK-D, and porous SiLK® semiconductor dielectric resins commercially available from Dow Chemical, and GX-3™, and GX-3P™ semiconductor dielectric resins commercially available from Honeywell.

The thin film 12 can be formed using a vapor deposition technique, such as chemical vapor deposition (CVD), plasma enhanced CVD (PECVD), atomic layer deposition (ALD), plasma enhanced ALD (PEALD), physical vapor deposition (PVD), or ionized PVD (iPVD), or a spin-on technique, such as those offered in the Clean Track ACT 8 SOD (spin-on dielectric), ACT 12 SOD, and Lithius coating systems commercially available from Tokyo Electron Limited (TEL). The Clean Track ACT 8 (200 mm), ACT 12 (300 mm), and Lithius (300 mm) coating systems provide coat, bake, and cure tools for SOD materials. The track system can be configured for processing substrate 10 sizes of 100 mm, 200 mm, 300 mm, and greater. Other systems and methods for forming a thin film 12 on a substrate 10 are well known to those skilled in the art of both spin-on technology and vapor deposition technology.

The ARC layer 20 possesses anti-reflective properties suitable for use as an anti-reflective coating and should withstand degradation during the photo-resist 16 removal step. Resistance to degradation during removal of the photo-resist 16 allows for selective removal of the photo-resist 16 using standard plasma ashing processes while leaving the sacrificial structure 14 intact. The ARC layer 20 may further include silicon. Additionally, according to an embodiment of the invention, the ARC layer 20, when etched, has mechanical properties sufficient to withstand the stresses associated with the deposition of a spacer layer 24. For example, a silicon-containing ARC material has a higher strength than standard organic ARC materials, and it thus provides better selectivity between the photo-resist 16 and ARC layer 20 and, hence, will be better able to withstand the stripping/ashing plasma and the stress induced during deposition of spacer layer 24, thereby allowing for better profile control. Suitable materials for use in the ARC layer 20 include, for example, antireflective coatings containing silicon that are commercially available from Dow Corning, Brewer Science, Inc., JSR Corp., Rohm and Haas, and Shin Etsu Chemical Co., Ltd.

Alternatively, rather than a silicon-containing ARC layer 20, the sacrificial structure 14 may include a multi-layer arrangement that includes one or more silicon compounds and one or more materials that have anti-reflective properties, such as amorphous carbon. The silicon compounds add strength and selectivity to the multi-layer sacrificial structure 14.

The ARC layer 20 may be applied and selectively removed by a wet-patterning process using a coating/developing system, though the embodiment is not so limited. In another embodiment, the ARC layer 20 may be applied and selectively removed by a dry-patterning process comprising a coating/developing system in combination with a dry etch tool. In one embodiment, a thickness of the ARC layer 20 may be between about 50 nanometers and about 100 nanometers. In another embodiment, the thickness of the ARC layer 20 may be between about 20 nanometers and about 50 nanometers. In an alternative embodiment, the thickness of the ARC layer 20 may be between about 100 nanometers and about 300 nanometers.

The photo-resist layer 16 may comprise 248 nm (nanometer) resists, 193 nm resists, 157 nm resists, or EUV (extreme ultraviolet) resists. The photo-resist layer 16 can be formed using a track system. For example, the track system can comprise a Clean Track ACT 8, ACT 12, or Lithius resist coating and developing system commercially available from Tokyo Electron Limited (TEL). Other systems and methods for forming a photo-resist layer 16 film on a substrate 10 are well known to those skilled in the art of spin-on resist technology. The coating of the photo-resist layer 16 may include any or all processes known to those skilled in the art of preparing such films including, but not limited to, performing a cleaning process prior to the coating process, performing a post-application bake (PAB) following the coating process, etc.

The optional hardmask layer 22 may include silicon oxide (SiOₓ), silicon nitride (SiNₓ), silicon carbide (SiCₓ), silicon oxynitride (SiOₓN_{y}), silicon carbonitride (SiCₓN_{y}), or amorphous carbon, or any combination of two or more thereof. These materials may be deposited using a chemical vapor deposition (CVD) process. The planarization layer may include an OPL comprised of a photo-sensitive organic polymer or an etch type organic compound, but is not so limited. For instance, the photo-sensitive organic polymer may be polyacrylate resin, epoxy resin, phenol resin, polyamide resin, polyimide resin, unsaturated polyester resin, polyphenylenether resin, polyphenylenesulfide resin, or benzocyclobutene (BCB). These materials may be formed using spin-on techniques.

In the embodiments shown, spacers 28 are formed from a spacer layer 24 formed on sacrificial structure 14. The technique of conformally depositing a spacer layer 24 may include a CVD process, a plasma enhanced CVD process, an atomic layer deposition (ALD) process, a plasma enhanced ALD process, or more generally, a monolayer deposition process.

Monolayer deposition (MLD), or atomic layer deposition, is based on the principle of the formation of a saturated monolayer of reactive precursor molecules by chemisorption. A typical MLD process for forming an AB film, for example, on a substrate consists of injecting a precursor or reactant A (R_{A}) for a period of time in which a saturated monolayer of A is formed on the substrate. Then, the precursor or reactant A (R_{A}) is purged from the chamber using an inert gas, G_{I}. This is followed by injecting precursor or reactant B (R_{B}) into the chamber, also for a period of time, to combine B with A thus forming the layer AB on the substrate. Then, the precursor or reactant B (R_{B}) is purged from the chamber. This process of introducing precursor or reactant A (R_{A}), purging the reactor, introducing precursor or reactant B (R_{B}), and purging the reactor can be repeated a number of times to achieve an AB film of a desired thickness. Alternatively, when forming an AB film, a precursor containing ABC is adsorbed on the substrate during the first step, and C is removed during the second step.

Embodiments of the invention will now be further described with sequential reference to the figures, in which like reference numerals are used to refer to like parts. According to an embodiment of the invention depicted schematically in FIGS. 1A through 1F, a film stack 100 is formed wherein a thin film 12 is formed on a substrate 10 and a sacrificial structure 14 is formed on the thin film 12 followed by a photo-resist layer 16 being formed on the sacrificial structure 14. The sacrificial structure 14 includes an ARC layer 20. The sacrificial layer 14 can include a silicon-containing ARC layer 20. Alternatively, the sacrificial layer 14 consists of a silicon-containing ARC layer 20.

As illustrated in FIG. 1A, an image pattern 26 is created in the photo-resist layer 16 using standard photolithographic techniques as known to one skilled in the art. For example, the photo-resist layer 16 is exposed to electromagnetic radiation through a reticle in a dry or wet photo-lithography system to create an image of the pattern 26. The image pattern 26 can be imaged in the photo-resist layer 16 using any suitable conventional stepping lithographic system, or scanning lithographic system. For example, the photo-lithographic system may be commercially available from ASML Netherlands B.V. (DeRun 6501, 5504 DR Veldhoven, The Netherlands), or Canon USA, Inc., Semiconductor Equipment Division (3300 North First Street, San Jose, Calif. 95134). Photo-resist layer 16 is then developed to form the image pattern 26 using a developing solvent in a developing system, such as a track system, to remove the imaged (irradiated) portions. For example, the track system can comprise a Clean Track ACT 8, ACT 12, or Lithius resist coating and developing system commercially available from Tokyo Electron Limited (TEL). The developing of the photo-resist layer 16 may include any or all processes known to those skilled in the art of preparing such films including, but not limited to, performing a post-exposure bake (PEB) prior to the developing process, performing a hard bake following the developing process, etc.

As shown in FIG. 1B, the image pattern 26 developed in the photo-resist layer 16 is transferred to the underlying sacrificial structure 14, in this case an ARC layer 20, using an etching or stripping process to form the image pattern 26 in the sacrificial structure 14. An etching process may include any combination of wet or dry etching processes as are known to those having ordinary skill in the art. The dry etching processes may include dry plasma etching processes or dry non-plasma etching processes or combinations thereof. For example, fluoro-carbon chemistry or halogen-containing chemistry may be used to etch the ARC layer 20. Additionally, for example, a CₓF_{y}-based process chemistry, or a CₓF_{y}H_{z}-based process chemistry, or both a CₓF_{y}-based process chemistry and a CₓF_{y}H_{z}-based process chemistry may be used to etch ARC layer 20. Additionally yet, for example, CH₂F₂ and CHF₃ may be used to etch a silicon-containing ARC layer 20. Further, a SF₆-based chemistry may be used to etch the ARC layer 20.

As shown in FIG. 1C, the photo-resist layer 16 is removed from the sacrificial structure 14 and the sacrificial structure 14 is trimmed using an etching process, leaving the image pattern 26 formed in the sacrificial structure 14. An etching process may include any combination of wet or dry etching processes as are known to those having ordinary skill in the art. The dry etching processes may include dry plasma etching processes or dry non-plasma etching processes or combinations thereof. For example, oxygen or fluorocarbon chemistry may be used in the etching process at this step.

As shown in FIG. 1D, a spacer layer 24 is conformally deposited over the image in the sacrificial structure 14. The spacer layer 24 may be any material suitable for spacer 28 formation known to one having skill in the art, for example, a spacer layer 24 of silicon dioxide or silicon nitride may be formed over the etched sacrificial structure 14 and the exposed surfaces of the underlying thin film 12 using the techniques described above and as are known to those having ordinary skill in the art.

As shown in FIG. 1E, the conformally deposited spacer layer 24 is etched back using an etching process to remove horizontal portions 30 of the spacer layer 24 while substantially leaving vertical portions 32 of the spacer layer 24. For example, an etching process may include any combination of wet or dry etching processes as are known to those having ordinary skill in the art. The dry etching processes may include dry plasma etching processes or dry non-plasma etching processes or combinations thereof. For example, the deposited spacer layer 24 may be etched using fluorocarbon chemistry or fluoro-hydrocarbon chemistry, or both.

Finally, as shown in FIG. 1F, portions of sacrificial structure 14 not overlaid by the etched spacer layer 24 are removed using an etching process, leaving spacers 28 that define an image pattern 50. For example, an etching process may include any combination of wet or dry etching processes as are known to those having ordinary skill in the art. The dry etching processes may include dry plasma etching processes or dry non-plasma etching processes or combinations thereof. For example, fluorocarbon chemistry or halogen-containing chemistry may be used to etch the remaining sacrificial structure 14. Additionally, for example, a CₓF_{y}-based process chemistry, or a CₓF_{y}H_{z}-based process chemistry, or both a CₓF_{y}-based process chemistry and a CₓF_{y}H_{z}-based process chemistry may be used to etch the remaining sacrificial structure 14. Additionally yet, for example, CH₂F₂ and CHF₃ may be used to etch the remaining sacrificial structure 14. Further, a SF₆-based chemistry may be used to etch the remaining sacrificial structure 14.

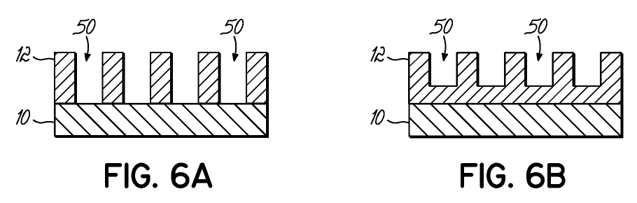

The steps shown in FIGS. 1A through 1F illustrate one embodiment of the invention for creating spacers 28 that may then be utilized as a mask to transfer the image pattern 50 to all or a portion of an underlying layer such as thin film 12, as illustrated in FIGS. 6A and 6B.

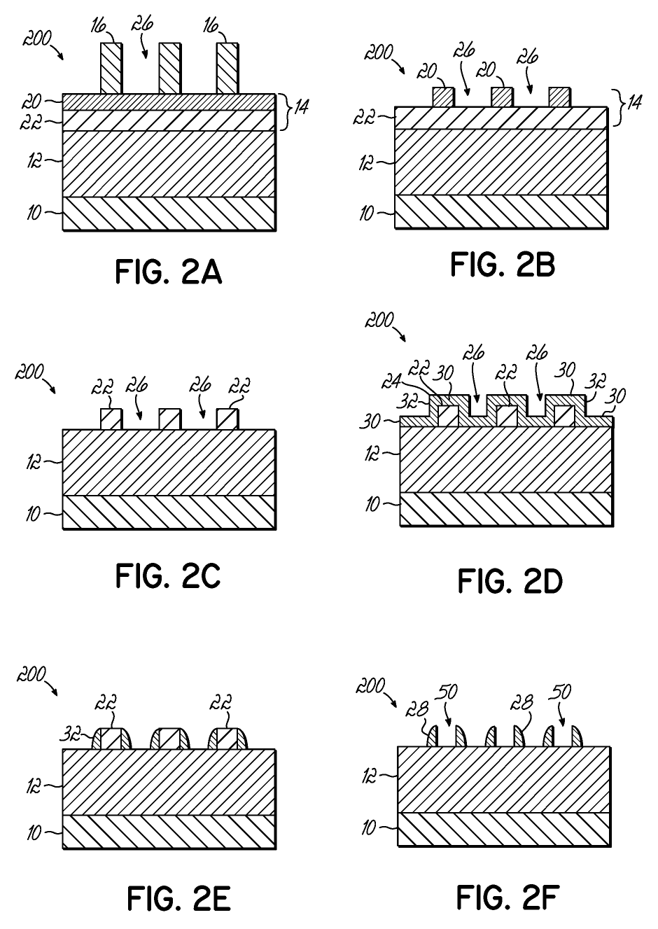

According to another embodiment of the invention depicted schematically in FIGS. 2A through 2F, a film stack 200 is formed wherein a thin film 12 is formed on a substrate 10, a sacrificial structure 14 is formed on the thin film 12, and a photo-resist layer 16 is then formed on the sacrificial structure 14. The sacrificial structure 14 includes a hard mask layer 22 formed on the thin film 12 and an ARC layer 20 formed on the hard mask layer 22.

The ARC layer 20 may comprise a silicon-containing ARC layer. Further, the ARC layer 20 may consist of a silicon-containing ARC layer. The inventors have discovered that the use of the silicon-containing ARC layer enables double patterning of thin film 12 since the silicon-containing ARC layer provides adequate mechanical properties for withstanding the ARC layer patterning process, the conformal deposition over the standing ARC layer structures, and the subsequent removal process(es).

The hardmask layer 22 may include silicon oxide (SiOₓ), silicon nitride (SiNₓ), silicon carbide (SiCₓ), silicon oxynitride (SiOₓN_{y}), silicon carbonitride (SiCₓN_{y}), or amorphous carbon, or any combination of two or more thereof. These materials may be deposited using a chemical vapor deposition (CVD) process.

As illustrated in FIG. 2A, an image pattern 26 is formed (imaged and developed) in the photo-resist layer 16 using standard photolithography techniques as described above. As shown in FIG. 2B, the image pattern 26 is then transferred to the ARC layer 20 of the sacrificial structure 14 and the photo-resist layer 16 is removed using standard etching processes as described above. The ARC layer 20 may be etched and the remaining photo-resist layer 16 may be removed using standard etching processes as previously described. As shown in FIG. 2C, the image pattern 26 is transferred to the hard mask layer 22 from the ARC layer 20 using standard etching processes as described above.

As shown in FIG. 2D, a spacer layer 24 is conformally deposited over the image pattern 26 formed in the hard mask layer 22 and the substrate 10. The spacer layer 24 may be any material suitable for spacer 28 formation previously described such as, for example, silicon dioxide or silicon nitride. As shown in FIG. 2E, the spacer layer 24 is then etched back to remove horizontal portions 30 of the spacer layer 24 while substantially leaving the vertical portions 32 of the spacer layer 24 intact as described above. As illustrated in FIG. 2F, the remaining hard mask layer 22 is removed from the thin film 12 using standard etching processes as described above, leaving spacers 28 that define an image pattern 50.

The steps shown in FIGS. 2A through 2F illustrate another embodiment of the invention for creating spacers 28 that may then be utilized as a mask to transfer an image pattern 50 to all or a portion of the underlying layer such as thin film 12, as illustrated in FIGS. 6A and 6B.

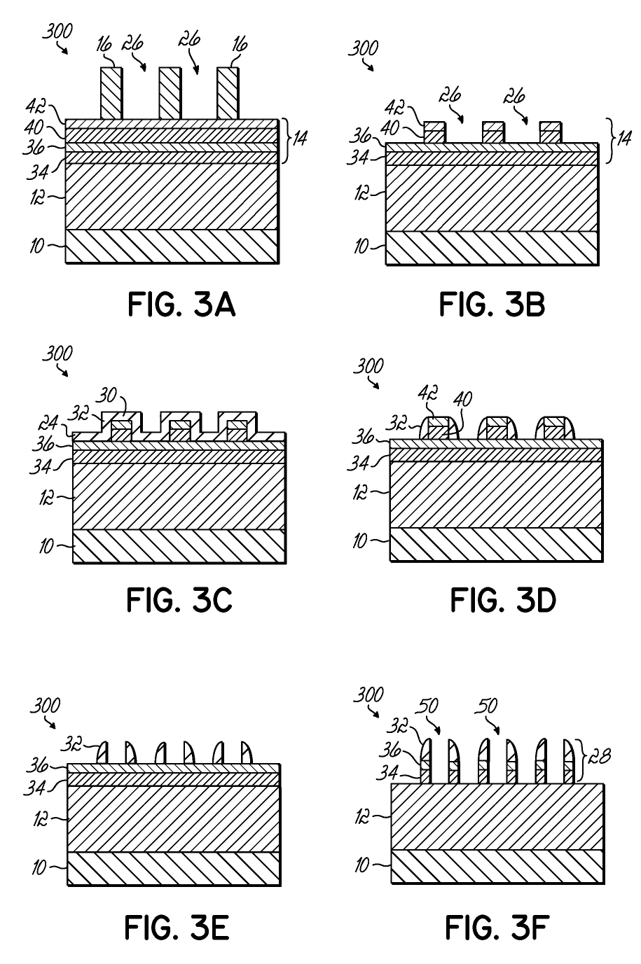

According to another embodiment depicted schematically in FIGS. 3A through 3F, the method of the invention may be used with a film stack 300 having a sacrificial structure 14 that comprises various layers that serve as an anti-reflective coating and/or a hard mask, that provide etching selectivity relative to the photo-resist 16, and that are capable of withstanding the stresses of depositing the spacer layer 24. For example, as seen in FIG. 3A, the sacrificial structure 14 formed over the thin film 12 may comprise a first layer of amorphous carbon 34 formed directly on the thin film 12 over which a layer of silicon dioxide 36 is formed. Over the layer of silicon dioxide 36 can be formed a second layer of amorphous carbon 40 on which a layer of silicon-containing ARC layer 42 may be formed. The photo-resist layer 16 can then be formed over the multilayered sacrificial structure 14. An image pattern 26 is formed (imaged and developed) in the photo-resist layer 16 as previously described using standard photolithography techniques.

The image pattern 26 is transferred to all or a portion of the underlying sacrificial structure 14 using etching processes as previously described. For example, as illustrated in FIG. 3B, the image pattern 26 is etched in the silicon-containing ARC layer 42 and second amorphous carbon 40 layers of the sacrificial structure 14.

As shown in FIG. 3C, a spacer layer 24 is conformally deposited over the etched surfaces of the sacrificial structure 14. The spacer layer 24 may be any material suitable for spacer 28 formation known to one having skill in the art such as, for example, silicon dioxide or silicon nitride. As shown in FIG. 3D, the spacer layer 24 is then etched back through the horizontal portions 30 of the spacer layer 24 while substantially leaving the vertical portions 32 of the spacer layer 24 intact.

As shown in FIG. 3E, the silicon nitride 42 and amorphous carbon 40 layers that are sandwiched between the remaining portions of the etched-back spacer layer 24 are removed using etching process as previously described. Finally, as seen in FIG. 3F, the remaining layers of sacrificial structure 14, i.e. the silicon dioxide 36 and first amorphous carbon 34 layers, that are not overlaid by the etched spacer layer 24 are removed using previously described etching processes, leaving spacers 28 that comprise the vertical portions 32 of the etched spacer layer 24 and remaining overlaid portions of the silicon dioxide 36 and first amorphous carbon 34 layers, and which define an image pattern 50.

The steps shown in FIGS. 3A through 3F illustrate another embodiment of the invention for creating spacers 28 that may then be utilized as a mask to transfer an image pattern 50 to all or a portion of the underlying layer such as thin film 12, as illustrated in FIGS. 6A and 6B.

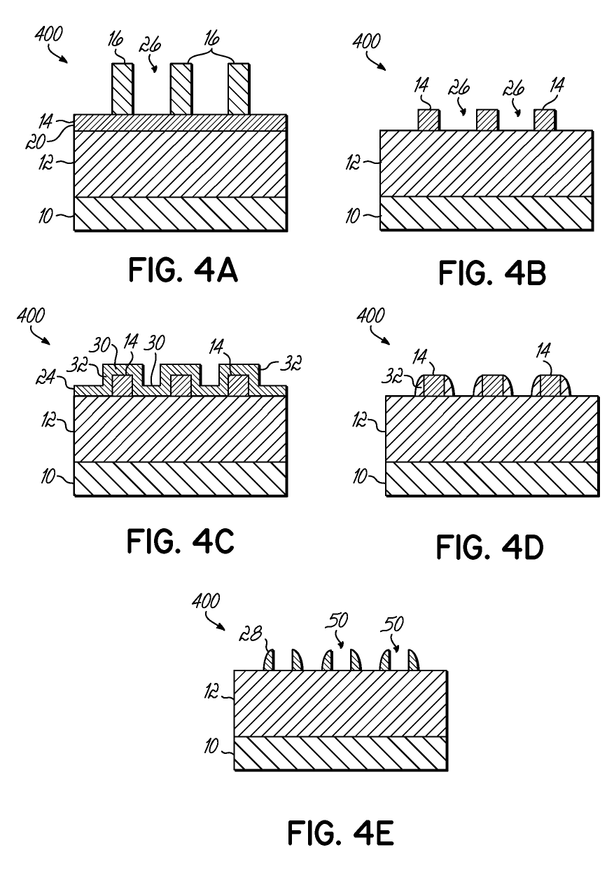

In another embodiment of the invention, illustrated in FIGS. 4A through 4E, a film stack 400 is formed that comprises a thin film 12 that is formed over a substrate 10 and a sacrificial structure 14 consisting of a silicon-containing ARC layer 20 that is formed over thin film 12. A photo-resist layer 16 is formed over the sacrificial structure 14. As illustrated in FIG. 4A, an image pattern 26 is formed (imaged and developed) in the photo-resist layer 16 using standard photolithography techniques as previously described. As shown in FIG. 4B, the image pattern 26 is then transferred from the photo-resist layer 16 to the sacrificial structure 14, and the remaining photo-resist layer 16 is removed using etching processes as described above.

As seen in FIG. 4C, a spacer layer 24 is conformally deposited over the etched sacrificial structure 14 and the exposed surface of the thin film 12 using the previously described techniques. The spacer layer 24 may be any material suitable for spacer 28 formation known to one having skill in the art such as, for example, silicon dioxide or silicon nitride. As illustrated in FIG. 4D, the conformally deposited spacer layer 24 is then etched back using an etching process as described above to remove horizontal portions 30 of the spacer layer 24 while substantially leaving the vertical portions 32 of the spacer layer 24 intact. As shown in FIG. 4E, the remaining sacrificial structure 14 that is sandwiched between the etched back portions of the deposited spacer layer 24 is removed using an etching process as previously described, leaving spacers 28 that define an image pattern 50.

The steps shown in FIGS. 4A through 4E illustrate yet another embodiment of the invention for creating spacers 28 that may then be utilized as a mask to transfer an image pattern 50 to all or a portion of the underlying layer such as thin film 12, as illustrated in FIGS. 6A and 6B.

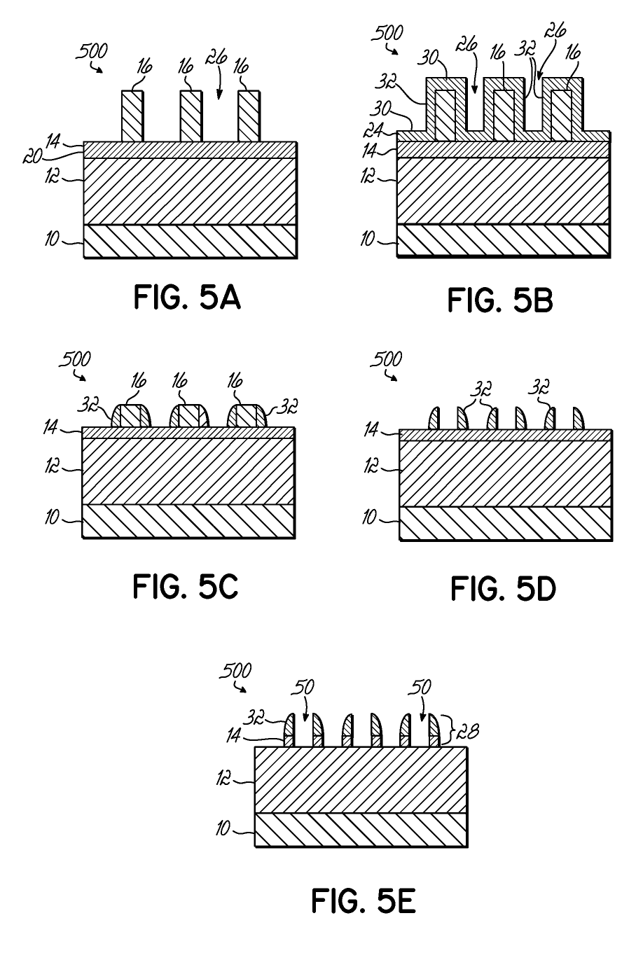

In another embodiment of the invention as illustrated in FIGS. 5A through 5E, a film stack 500 is formed that comprises a thin film 12 formed over a substrate 10 and a sacrificial structure 14 comprising a silicon-containing ARC layer 20 that is formed over thin film 12. A photo-resist layer 16 is formed over the sacrificial structure 14. As seen in FIG. 5A, an image pattern 26 is formed (imaged and developed) in the photo-resist layer 16 using standard photolithography techniques as previously described.

As shown in FIG. 5B, a spacer layer 24 is conformally deposited over the image pattern 26 in the photo-resist layer 16 using the techniques described above. The spacer layer 24 may be any material suitable for spacer 28 formation known to one having skill in the art such as, for example, silicon dioxide or silicon nitride. As shown in FIG. 5C, the spacer layer 24 and the photo-resist layer 16 are then etched back using standard etching processes as previously described to remove horizontal portions 30 of the spacer layer 24 while leaving at least a fraction of the vertical portions 32 of the spacer layer 24 intact.

As shown in FIG. 5D, the remaining photo-resist layer 16 that is not overlaid by the etched monolayer 24 is removed using an etching process as previously described. Finally, as seen in FIG. 5E, any sacrificial structure 14, i.e. the ARC layer 20, that is not overlaid by the etched spacer layer 24 is removed using standard etching processes as previously described, leaving spacers 28 that define an image pattern 50.

The steps shown in FIGS. 5A through 5E illustrate still another embodiment of the invention for creating spacers 28 that may then be utilized as a mask to transfer an image pattern 50 to all or a portion of the underlying layer such as thin film 12, as illustrated in FIGS. 6A and 6B.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

What is claimed is:

1. A method of patterning a thin film on a substrate comprising:
forming a sacrificial structure over the thin film and forming a photo-resist layer over the sacrificial structure, wherein said sacrificial structure comprises a silicon-containing anti-reflective coating (ARC) layer;
creating a pattern in one or both of the photo-resist layer or the sacrificial structure;
conformally depositing a spacer layer over the pattern;
etching back the monolayer to remove horizontal portions of the spacer layer while substantially leaving vertical portions of the spacer layer; and
removing any of the sacrificial structure or the photo-resist layer not overlaid by the etched monolayer.

2. The method of claim 1 wherein the pattern is created by imaging the photo-resist layer with an image pattern, developing the photo-resist layer to form the image pattern; and etching the sacrificial structure to transfer the image pattern from the photo-resist layer to the sacrificial structure.

3. The method of claim 2 wherein the sacrificial structure is etched using dry etching techniques.

4. The method of claim 1 wherein the pattern is formed in the photo-resist layer and the spacer layer is conformally deposited over the pattern in the photo-resist layer.

5. The method of claim 1 wherein the pattern is formed in the sacrificial structure and the spacer layer is conformally deposited over the pattern in the sacrificial structure.

6. The method of claim 1 wherein the sacrificial structure further includes another anti-reflective coating.

7. The method of claim 1 wherein the sacrificial structure consists of the silicon-containing anti-reflective coating layer.

8. The method of claim 1 wherein the sacrificial structure further includes a hard mask layer underlying the silicon-containing ARC layer.

9. The method of claim 1 wherein the sacrificial structure further includes amorphous carbon.

10. The method of claim 1 wherein the pattern is created using lithography.

11. A method of patterning a thin film on a substrate, comprising:
forming a sacrificial structure over the thin film, the sacrificial structure having anti-reflective properties and comprising silicon;
forming a photo-resist over the sacrificial structure;
imaging the photo-resist layer with an image pattern;
developing the photo-resist layer to form the image pattern;
etching the sacrificial structure to transfer the image pattern from the photo-resist layer to the sacrificial structure;
removing the photo-resist layer;
conformally depositing a spacer layer on the sacrificial structure;
etching back the spacer layer to remove horizontal portions of the spacer layer while substantially leaving vertical portions of the spacer layer; and
removing any of the sacrificial structure not overlaid by the etched spacer layer.

12. The method of claim 11 wherein the sacrificial structure consists of a silicon-containing ARC layer.

13. The method of claim 11 wherein the sacrificial structure further includes a hard mask.

14. The method of claim 11 wherein the sacrificial structure further includes amorphous carbon.

15. The method of claim 11 wherein the image pattern is created using lithography.

16. The method of claim 11 wherein the sacrificial structure is etched using dry etching techniques.

17. A method of patterning a thin film on a substrate, comprising:
forming a sacrificial structure over the thin film, the sacrificial structure having anti-reflective properties and comprising silicon;
forming a photo-resist over the sacrificial structure;
imaging the photo-resist layer with an image pattern;
developing the photo-resist layer to form the image pattern;
conformally depositing a spacer layer over the image pattern in the photo-resist layer;
etching back the spacer layer to remove horizontal portions of the spacer layer while leaving at least a fraction of vertical portions of the spacer layer;
removing the photo-resist layer; and
removing any of the sacrificial structure not overlaid by the etched spacer layer.

18. The method of claim 17 wherein the sacrificial structure consists of a silicon-containing ARC layer.

19. The method of claim 17 wherein the sacrificial structure further includes a hard mask.

20. The method of claim 17 wherein the sacrificial structure further includes amorphous carbon.

21. The method of claim 17 wherein the image pattern is created using lithography.

22. The method of claim 17 wherein the sacrificial structure is etched using dry etching.
